(19) United States
(12) Patent Application Publication
(10) Pub. No.: US 2009/0219704 A1
(43) Pub. Date: Sep. 3, 2009

(54) PRINTED BOARD HOLDING CASE, HIGH FREQUENCY COMPONENT, AND METHOD FOR PRODUCING THE SAMES

(76) Inventor: Atsumi YOKOYAMA, Osaka-shi (JP)

Correspondence Address: BIRCH STEWART KOLASCH & BIRCH, PO BOX 747, FALLS CHURCH, VA, 22040-0747, US

(21) Appl. No.: 12/395,189

(22) Filed: Feb. 27, 2009

(30) Foreign Application Priority Data
Feb. 29, 2008 (JP) 2008-050643

(51) Int. Cl. H05K 5/00; H01R 43/20

(52) U.S. Cl. 361/753; 29/876

(57) ABSTRACT

In a high frequency component, a case made up of metal having a shape of frame for containing a board includes tabs and stoppers. During producing of the high frequency component, the board is inserted from an opening on a side on which the tabs are provided. Each of the tabs has a height in a direction perpendicular to an insertion direction of the board, which becomes lower toward upstream in the insertion direction. Each of the tabs has elasticity so as to return to its original state after being pushed toward an inner side surface of the case by a force applied from upstream side in the insertion direction. By this, the board can be easily inserted and fixed between the tabs and the stoppers in the case. This makes it possible to provide a printed board holding case to which a printed board can be easily inserted and sufficiently fixed.

This Nonprovisional application claims priority under 35 U.S.C. §119(a) on Patent Application No. 050643/2008 filed in Japan on Feb. 29, 2008, the entire contents of which are hereby incorporated by reference.

### TECHNICAL FIELD

The present invention relates to a printed board holding case, which is for use in an electronic device such as a tuner including a high frequency circuit, for containing a printed board on which a high frequency circuit is provided. The present invention also relates to a high frequency component including the printed board holding case, and to a method for producing the printed board holding case and the high frequency component.

### BACKGROUND ART

Generally, an electronic device, such as a tuner, including a high frequency circuit is subjected to an electromagnetic shield so as to prevent an unintended radio emission, i.e., a so-called unwanted radiation to other circuits. Such an electromagnetic shield for the electronic device can be realized by, for example, a method in which a printed board including a high frequency circuit is fixed inside a metal frame of a printed board case.

Such a method for fixing a printed board inside a case is disclosed in Patent Literature 1 and Patent Literature 2. According to Patent Literature 1, a printed board is fixed inside a case as follows: a printed board, having a slit that is fitted in an insertion piece of a metal frame of a case, is attached to the case, and then a solder is applied to a solder pool section, which is formed when the insertion piece is folded. In Patent Literature 2, a printed board is fixed inside a holding case as follows: part of a metal frame which is in contact with a printed board is folded after the printed board is inserted into a holding case, and then a solder is applied to the part thus folded.

The following description deals with an arrangement of a conventional holding case, and a method for producing a high frequency component by fixing a printed board to the holding case, with reference to FIGS. 10 through 14. FIGS. 10 through 14 are schematic views each showing a conventional process of fixing a printed board 1 to a holding case 13.

As shown in FIG. 10, a printed board 1 is fixed to a case 13 that has a frame shape so as to surround the printed board 1, thereby producing a high frequency component 12. The case 13 includes on its side surfaces stoppers 14 and tab sections 15 so that the printed board 1 is fixed inside the case 13. The tab sections 15 are formed by making notches on the side surfaces of the case 13, respectively, so that each of the notches has an L-shape and an inverted L-shape. The stoppers 14 are formed on the side surfaces of the case 13 so as to protrude inside the case 13, in which the printed board 1 is to be contained. The step of producing the high frequency component 12 is carried out as follows: first, the printed board 1 is inserted into the case 13 as shown in FIG. 10. As shown in FIG. 11, the printed board 1 thus inserted is in contact with and supported by the stoppers 14 provided on the side surfaces of the case 13. Then, as shown in FIG. 12, the tab sections 15 are bent inside the case 13 so that the printed board 1 is sandwiched between and fixed by the stoppers 14 and the tab sections 15. Further, as shown in FIG. 13, a solder 16 is applied and soldered between the tab sections 15 and the board 1, so that the printed board 1 is electrically connected to the case 13.

### Citation List

Patent Literature 1

Japanese Patent Application Publication, Tokukaihei, No. 9-148778 (Publication Date: Jun. 6, 1997)

Patent Literature 2

Japanese Patent Application Publication, Tokukaihei, No. 9-260884 (Publication Date: Oct. 3, 1997)

However, according to the arrangement in Patent Literature 1, it is necessary that the slit which is fitted in the insertion piece on the metal frame of the case is provided in advance on the printed board which is to be contained inside the case. This causes an increase in producing process. Further, it is necessary that the printed board is subjected to a particular process. Therefore, the arrangement of Patent Literature 1 is not suitable for containing a general purpose printed board. According to the conventional arrangement disclosed in Patent Literature 2 and shown in FIGS. 10 through 14, it is necessary, in the process of producing the high frequency component, to separately carry out a step of folding the tab sections, that is, a bending step after the printed board is inserted into the case. In the bending step which is carried out with respect to the tab sections, a problem of difficulty in controlling a bending angle of the tab sections occurs. For example, a small bending angle causes the board to be unstable because the board is insufficiently fixed. On the other hand, a large bending angle causes a strain or a crack in the board, so that components mounted on the board become easy to break. Further, (i) a remaining stress caused in the bending step which is carried out to the tab sections and/or (ii) a force generated due to a difference in heat expansion coefficient between the case and the board are exerted on an area where the tab sections are bonded to the board with a solder. This causes a reduction in quality and reliability of the high frequency component.

### SUMMARY OF INVENTION

The present invention has been accomplished in view of the problems, and an object of the present invention is to (i) realize a holding case capable of easily fixing and containing, in the holding case, a printed board including a component such as a high frequency circuit, (ii) simplify an assembling operation of a high frequency component using the holding case, and (iii) provide the high frequency component improved in quality and reliability.

In order to attain the object, a printed board holding case in accordance with the present invention is a printed board holding case for containing a printed board inside a metal frame of the case, the metal frame including tab sections and supporting sections, each of which protrudes inside the metal frame so as to fix the printed board, each of said tab sections being obtained by a notch, which causes first and second line segments in the metal frame, each of the first and second line segments having first and second ends, the first ends coming in contact with each other, and said each of the tab sections being provided so that the metal frame is bent inside the metal frame along a fold line that connects the second ends of the first and second line segments of the notch, said supporting sections being provided downstream of said tab sections in an insertion direction of the printed board, and the printed board being contained so as to be sandwiched between respective of said tab sections and respective of said supporting sections.

With the arrangement, the tab sections are formed by notching the metal frame so that first and second line segments are caused, and then by bending a notch thus formed so that the notch protrudes inside the metal frame. Each of the first and second line segments has first and second ends, and the first ends are in contact with each other on downstream side in the insertion direction. An area surrounded by the first and second line segments and a fold line is bent inward along the fold line that connects the second ends of the first and second line segments. Each of the tab sections formed as described above has a slope in the insertion direction so as to become higher, toward downstream in the insertion direction, in height in a direction perpendicular to the insertion direction.

Therefore, when the printed board is inserted into the metal frame from an opening on a side on which the tab sections are provided, the printed board comes into contact with the tab section. Then, a force is applied to the printed board so that the printed board is contained between the tab sections and the supporting sections in the metal frame. This causes the force to be applied to the tab sections via the printed board from upstream side in the insertion direction. Since the tab sections have the slope and have elasticity in response to the force applied from the downstream side in the insertion direction, the tab section is pushed toward an inner side surface of the metal frame so as to be less bent along the fold line. In this way, the printed board is smoothly inserted along the tab sections.

The force is no longer applied to the tab sections after the printed board passes over the tab sections. Therefore, each of the tab sections returns to its original state by being bent along the fold line due to its metal elasticity. The printed board is in contact with surfaces of the tab sections in the original state, which surfaces are on the downstream side in the insertion direction. Therefore, the tab sections prevent the printed board from moving in the insertion direction by supporting the printed board on the upstream side in the insertion direction. The supporting sections are provided downstream side of the tab sections in the insertion direction so as to support the printed board on the downstream side. Therefore, the printed board can be sandwiched between and fixed by the tab sections and the supporting sections. As described above, it is possible to more smoothly insert the printed board and to surely fix, in the case, the printed board thus inserted. Note that a printed board in the present invention may be a printed circuit board (PCB) and a printed wiring board (PWB).

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1

FIG. 1 is a perspective view showing a high frequency component in accordance with one embodiment of the present invention.

FIG. 2

FIG. 2 is a perspective view showing a high frequency component in accordance with another embodiment of the present invention.

FIG. 3

FIG. 3 is an enlarged plan view of a part of a high frequency component in accordance with the present invention.

FIG. 4

FIG. 4(a) is an enlarged perspective view of a part of a high frequency component in accordance with the present invention. FIG. 4(b) is an enlarged cross-sectional view of the part of the high frequency component in accordance with the present invention.

FIG. 5

FIG. 5(a) is an enlarged perspective view of a part of a high frequency component in accordance with the present invention. FIG. 5(b) is an enlarged cross-sectional view of the part of the high frequency component in accordance with the present invention.

FIG. 6

FIG. 6(a) is an enlarged perspective view of a part of a high frequency component in accordance with the present invention. FIG. 6(b) is an enlarged cross-sectional view of the part of the high frequency component in accordance with the present invention.

FIG. 7

FIG. 7 is an enlarged plan view of a part of a high frequency component in accordance with the present invention.

FIG. 8

FIG. 8(a) is an enlarged perspective view of a part of a high frequency component in accordance with the present invention. FIG. 8(b) is an enlarged cross-sectional view of the part of the high frequency component in accordance with the present invention.

FIG. 9

FIG. 9 is a cross-sectional view of a high frequency component in accordance with an embodiment of the present invention.

FIG. 10

FIG. 10 is a perspective view showing a producing process of a conventional high frequency component.

FIG. 11

FIG. 11 is a perspective view showing a producing process of a conventional high frequency component.

FIG. 12

FIG. 12 is a perspective view showing a producing process of a conventional high frequency component.

FIG. 13

FIG. 13 is a perspective view showing a producing process of a conventional high frequency component.

### DESCRIPTION OF EMBODIMENTS

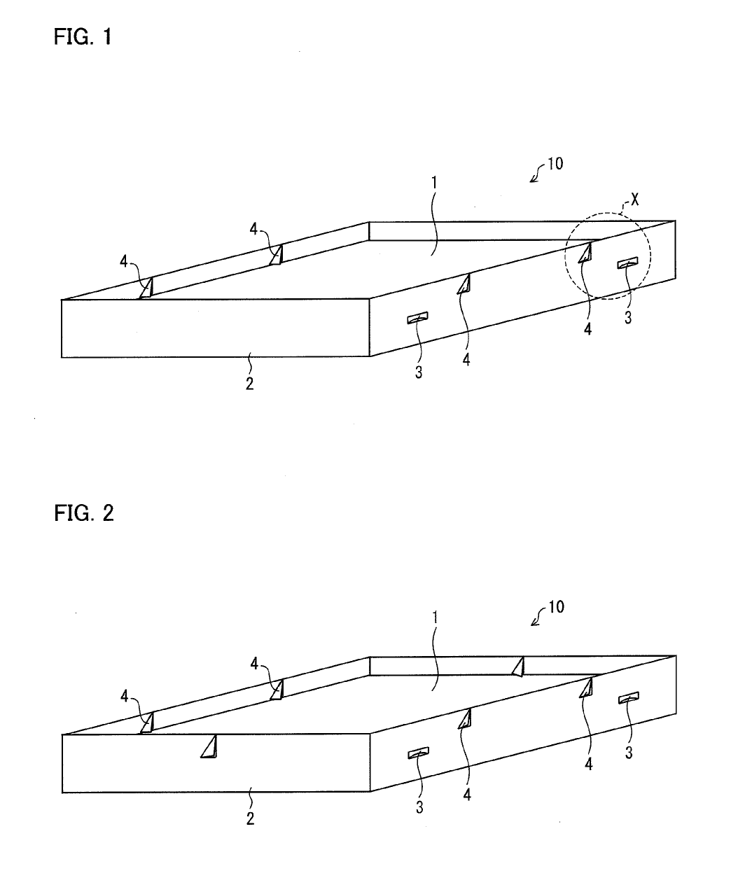

One embodiment of the present invention is described below with reference to FIGS. 1 through 9. The present embodiment describes a high frequency component 10 in which a case 2 (printed board holding case) contains a board 1 (printed board) on which a high frequency circuit is provided. However, the present invention is not limited to this.

An arrangement of a high frequency component 10 is described below with reference to FIG. 1. FIG. 1 is a perspective view showing the high frequency component 10 in accordance with one embodiment of the present invention. As shown in FIG. 1, the high frequency component 10 includes a board 1 and a case 2. The board 1 is contained inside the case 2. The case 2 is made up of a metal frame having elasticity. The board 1 is inserted into the case 2 from one side of an opening of the metal frame in an insertion direction which is substantially perpendicular to edges of the opening of the metal frame.

The case 2 includes tabs (tab sections) 4 and stoppers (supporting sections) 3, each of which protrudes inside the case 2. Specifically, two tabs 4 and two stoppers 3 are provided on a pair of inner side surfaces of the case 2, respectively, which inner side surfaces face each other inside the case 2. Note however that the number of the tabs 4 and the number of the stoppers 3 are not limited to specific ones, respectively. The tabs 4 and the stoppers 3 do not have to be provided only on the pair of the inner side surfaces that face each other, but can be provided on all of the inner side surfaces of the case 2 as shown in FIG. 2. FIG. 2 is a perspective view showing a high frequency component in accordance with another embodiment of the present invention.

The board 1 is sandwiched between the stoppers 3 and the tabs 4 that are provided above and below the board 1 in the insertion direction, respectively. This causes the board 1 to be in contact with the tabs 4 and the stoppers 3, so that the board 1 is fixed inside the case 2. In the present embodiment, the board 1 has a thickness that is substantially equal to a distance between respective ones of the tabs 4 and the stoppers 3 in the insertion direction of the board 1. This allows the board 1 to be firmly sandwiched between the tabs 4 and the stoppers 3.

The distance between respective ones of the tabs 4 and the stoppers 3 in the insertion direction of the board is preferably shorter than the thickness of the board 1, and is more preferably shorter by 0.02 mm to 0.05 mm than the thickness of the board 1. Further, it is preferable that the stoppers 3 are differently positioned from the tabs 4 in a direction perpendicular to the insertion direction of the board 1. It is more preferable that adjacent tab 4 and stopper 3 are provided so as to have a distance of 5 mm to 6 mm in the direction perpendicular to the insertion direction of the board 1. With the arrangement, it is possible to prevent the board 1 from being unstable inside the case 2 because the board 1 is fixed in the case 2 so as to be distorted like a spring.

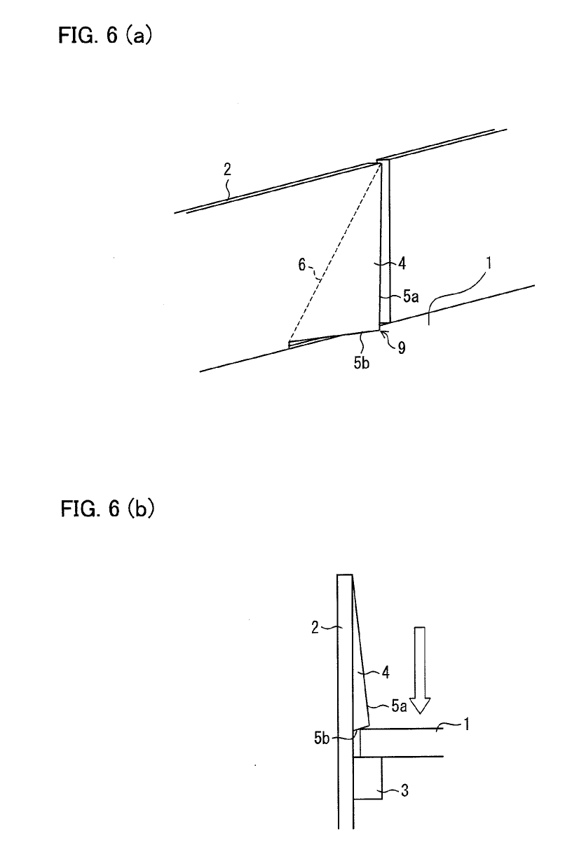

An arrangement of the tab 4 is described below in detail with reference to FIG. 6. FIG. 6(a) is an enlarged perspective view of a part enclosed by X in FIG. 1, and FIG. 6(b) is a cross-sectional view of the part. As shown in FIG. 6(a), a tab 4 is formed by a bending process so as to protrude inside the case 2. Specifically, a notch 5 is made in an inner side surface of the case 2 so that two line segments form an angle, and then the notch 5 is bent along a fold line 6 so that the tab 4 is defined by an area which is surrounded by the two line segments of the notch 5 and the fold line 6. Since the bending process is carried out with respect to the area which is surrounded by the two segments of the notch 5 and the fold line 6, the tab 4 is provided so as to protrude inside the case 2. Note that the fold line 6 is a line segment that connects one ends of the two line segments of the notch 5. The other ends of the two line segments of the notch 5 are in contact with each other. It follows that the tab 4 has a plane surface whose shape is triangle defined by the fold line 6 and two sides 5a and 5b, which correspond to the two line segments of the notch 5.

As shown in FIG. 6(b), the tab 4 has a height in the direction perpendicular to the insertion direction of the board 1, that is, a height from the side surface of the case 2 so that the height gradually becomes higher toward downstream in the insertion direction. A vertex 9 defined by the sides 5a and 5b of the tab 4 is arranged so as to be closer to an end of the side 5b than to an end of the side 5a. Therefore, the height of the tab 4 from the side surface of the case 2 becomes higher along the side 5a toward the downstream in the insertion direction of the board 1, and then becomes lower along the side 5b toward the downstream. This causes the side 5a to have a gentle slope in the insertion direction of the board 1, whereas the side 5b to have a relatively steep slope in the insertion direction of the board 1.

With the arrangement, in a case where the board 1 is inserted to the case 2 during producing of the high frequency component 10, that is, in a case where the board 1 is inserted to the case 2 in a direction indicated by an arrow shown in FIG. 6(b), the board 1 is inserted while pushing the tab 4 toward the inner side surface of the case 2 so that the tab 4 is less bent along the fold line 6. More specifically, the board 1 can easily be inserted into the case 2 along the side 5a which has the gentle slope in the insertion direction. After the board 1 passes over the side 5a of the tab 4, the tab 4 is no longer pushed toward the inner side surface of the case 2. As a result, the tab 4 returns to an original state because of its elasticity. This causes the board 1 to come into contact with the side 5b, which has the slope in the insertion direction, so that the board 1 can be prevented from moving backward.

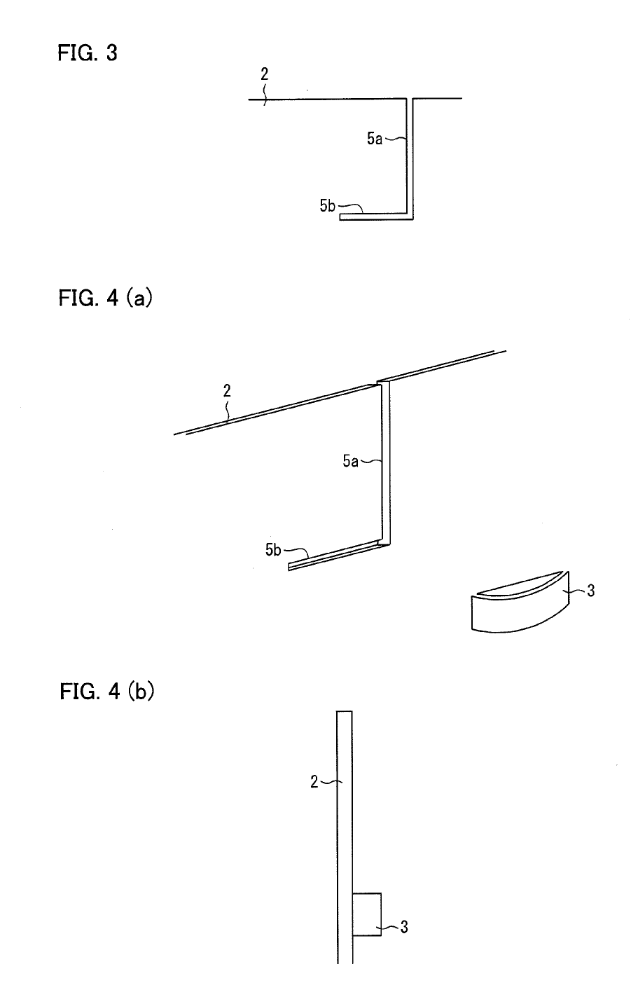

A notching process and a bending process for forming the tab 4 are described below in detail with reference to FIGS. 3 through 5 and FIGS. 7 through 9. As shown in FIG. 3, a case 2 is notched along (i) a first line segment, which starts from an edge of an open of a frame of the case 2 and extends toward downstream in an insertion direction of a board 1 and (ii) a second line segment, which extends at right angles with the first line segment, extends in a direction perpendicular to the insertion direction, and is in contact with an end of the first line segment, the end being downstream in the insertion direction. By this, two sides 5a and 5b of the tab 4 are formed. The side 5a of the tab 4 corresponds to the first line segment. The side 5b of the tab 4 corresponds to the second line segment. FIG. 3 is a front view showing a notch which has not yet been subjected to a bending process. Note however that the preset invention is not limited to this, provided that the foregoing conditions on arrangement are met.

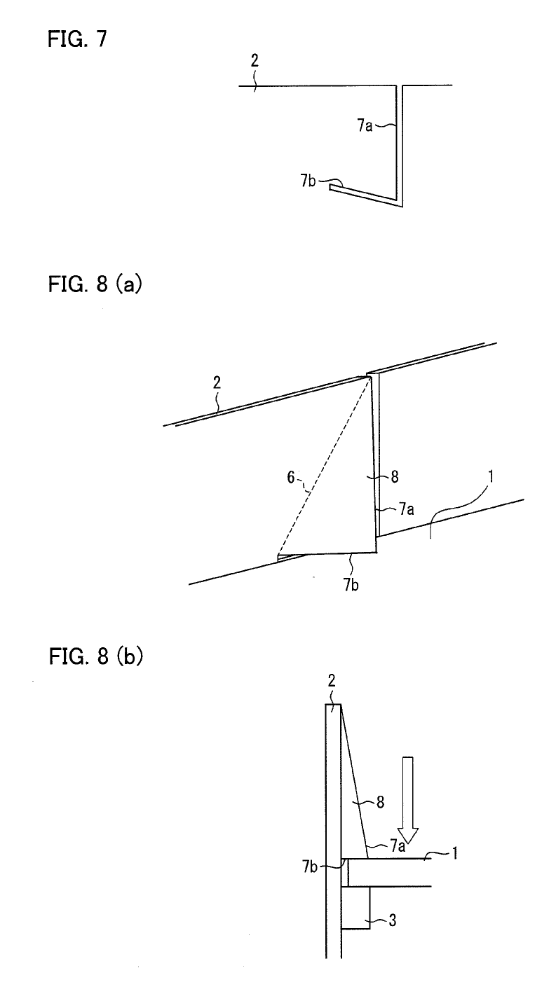

For example, as shown in FIG. 7, a case 2 is notched along (i) a first line segment, which starts from an edge of an open of a frame of the case 2 and extends toward downstream in an insertion direction of a board 1 and (ii) a second line segment, which extends to be at an acute angle to the first line segment and is in contact with an end of the first line segment, the end being downstream in the insertion direction. The first line segment corresponds to a side 7a of a tab 8. The second line segment corresponds to a side 7b of the tab 8. FIG. 7 is a front view showing a notch which has not yet been subjected to a bending process. In a bending process which is carried out with respect to a notch 7, an adjustment is carried out so that the side 7b is bent in the direction perpendicular to the insertion direction. This allows the side 7b of the tab 8 to be made parallel to the board 1 as shown in FIG. 8(a) and 8(b). FIG. 8(a) and 8(b) are enlarged views each showing the tab 8. This causes the side 7b to be in line contact (not point contact) with the board 1. As such, it is possible to more firmly fix the board 1 to the case 2.

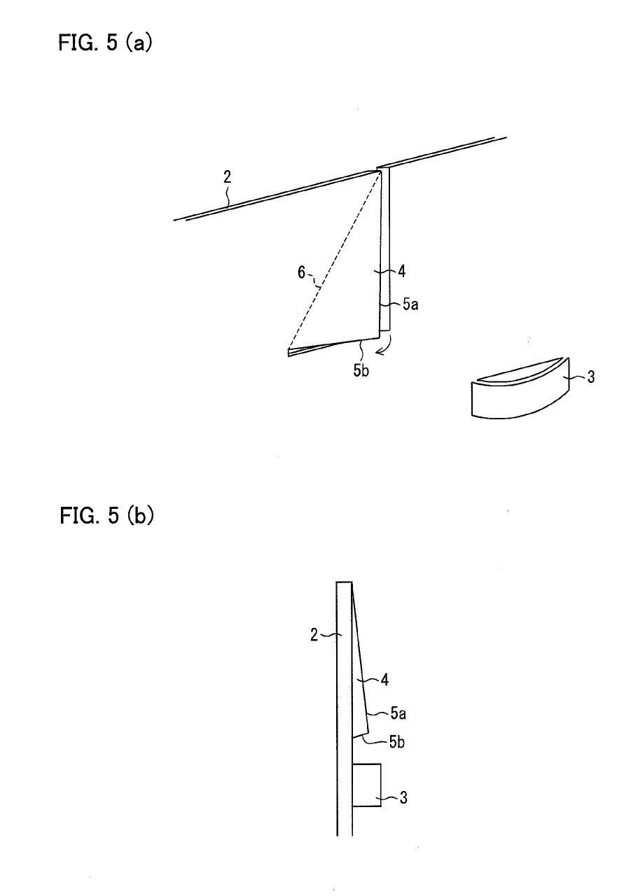

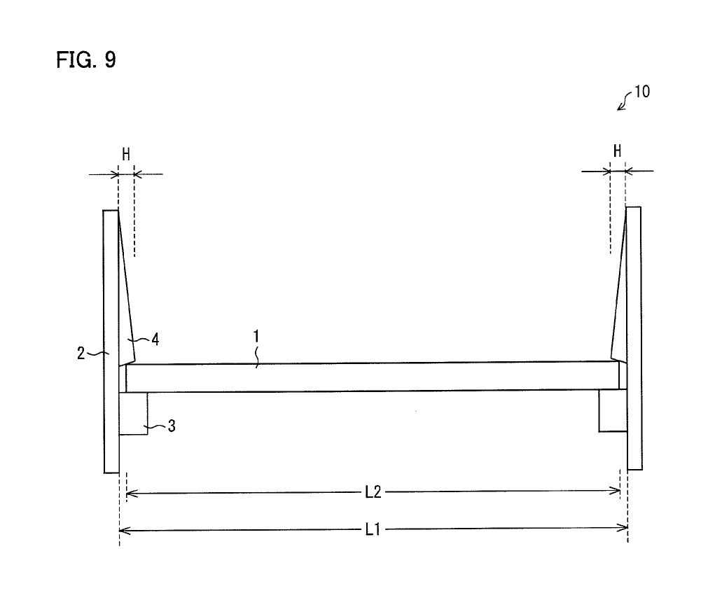

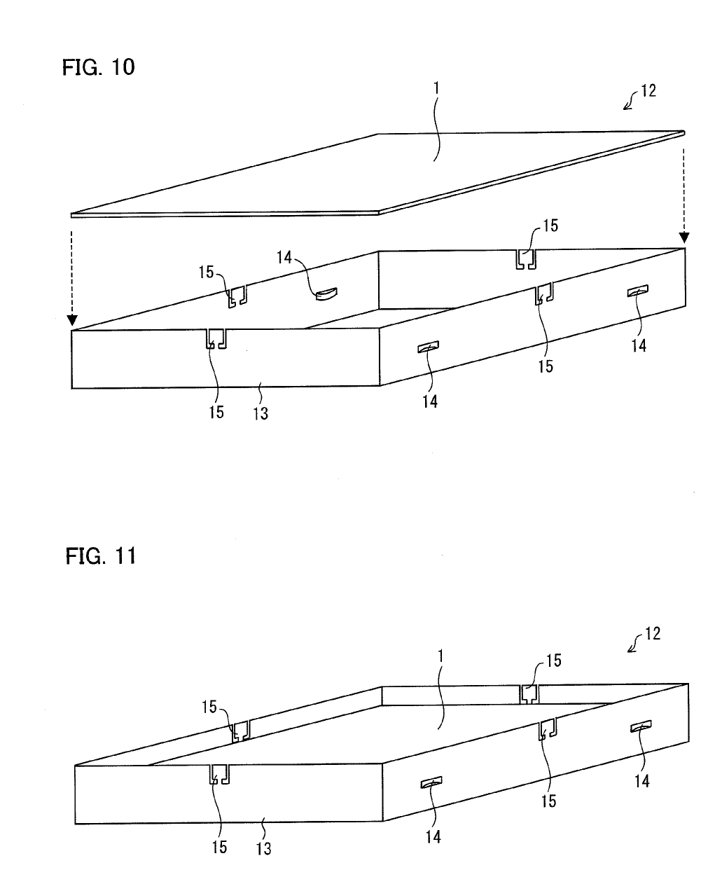

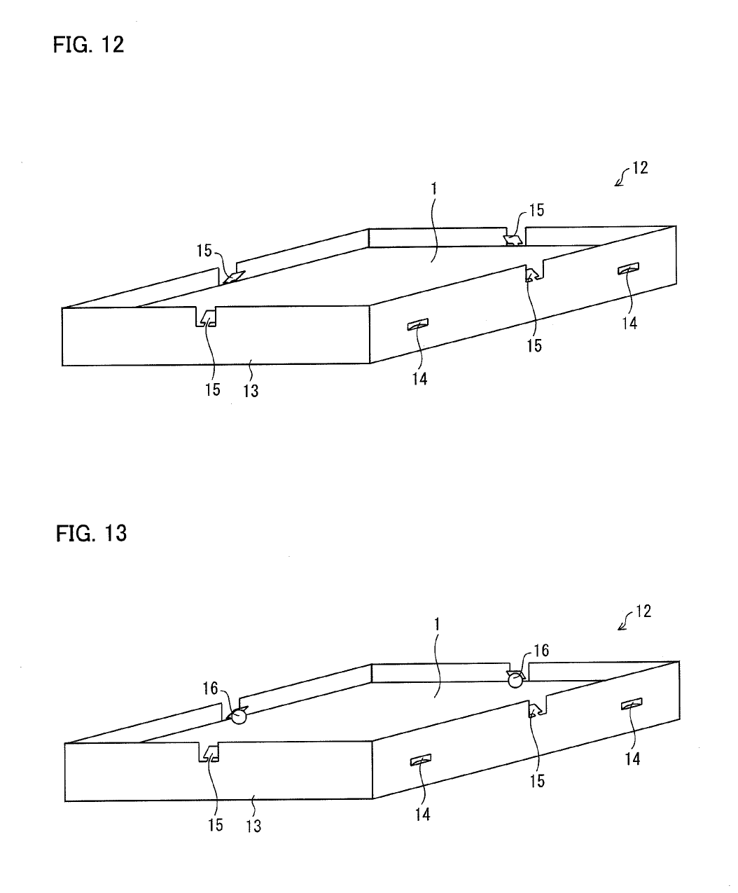

In a bending process in accordance with the present embodiment, an angle at which the tab 4 is bent is adjusted as follows. As shown in FIG. 5, the area which is surrounded by the sides 5a and 5b of the tab 4 and the fold line 6 is bent inward along the fold line 6 so that the side 5b of the tab 4 comes into contact with the board 1. Described below with reference to FIG. 9 is a height of the tab 4 in a direction perpendicular to the insertion direction of the board 1, that is, a distance from the inner side surface of the case 2 to the vertex 9 defined by the sides 5a and 5b. FIG. 9 is a cross-sectional view of a high frequency component 10 and shows a cross-section of a side surface of a case 2, on which a tab 4 and a stopper 3 are provided.

In FIG. 9, it is assumed that H indicates the height of the tab 4; L1 indicates a length of an inside of the case 2 in the direction perpendicular to the insertion direction, that is, a distance between a pair of opposed inner surfaces of the case 2; and L2 indicates a length of the board 1, which is contained inside the case 2, in the direction perpendicular to the insertion direction. It is preferable that H is greater by 0.1 mm or more than (L1−L2)/2, more preferably by 0.4 mm or more. It is possible that the tab 4 firmly fixes the board 1 to the case 2, in a case where the tab 4 has a height greater by 0.1 mm or more than (L1−L2)/2. Further, it is possible to suitably solder an area where the tab 4 is in contact with the board 1, in a case where the tab 4 has a height greater by 0.4 mm or more than (L1−L2)/2. It is preferable that H has an upper limit of greater by 0.6 mm than (L1−L2)/2.

The area where the tab 4 is in contact with the board 1 can be soldered. This causes the case 2 to be electrically connected to the board 1, so that the board 1 can have a reduced impedance. It is preferable that bottom parts of both triangular surfaces of the tab 4 are soldered so that the tab 4 is sandwiched between the solder. This allows prevention of a crack and the like in a soldered part due to heat cycle load.

Note that the stoppers 3 only have to protrude inside the case 2 to the same extent as the tab 4 so as to be in contact with the board 1 (see FIGS. 5(a) and 5(b)).

A method for producing a high frequency component 10 is described below with reference to FIGS. 4 through 6. First, during producing of a case 2, a notch and a stopper 3 are formed on a side surface of the case 2 as shown in FIGS. 4(a) and 4(b). FIG. 4(a) is a view showing the notch and the stopper 3 formed on the case 2, and FIG. 4(b) is a cross-sectional view of FIG. 4(a). Then, an area surrounded by sides 5a and 5b and a fold line 6 is folded inward along the fold line 6 that connects one ends of the sides 5a and 5b. By this, the tab 4 is formed, so that the case 2 in accordance with the present invention is completed.

Next, a board 1 is inserted to the case 2 as shown in FIGS. 6(a) and 6(b). The board 1 is inserted to the case 2 in a direction indicated by an arrow shown in FIG. 6(b), that is, the board 2 is inserted via the side 5a of the tab 4. The board 1 is inserted along the side 5a while pushing the tab 4 toward an inner side surface of the case 2. At the moment when the board 1 passes over a vertex 9 of the tab 4, the tab 4 returns to its original state due to its metal elasticity. This causes the tab 4 to be bent at an original bending angle. As a result, the board 1 is fitted in between the tab 4 and the stopper 3. By using the case 2 in accordance with the present invention in assembling the high frequency component 10 as described above, it is possible to easily insert the board 1 into the case 2, and to sufficiently fix the board 1 between the tab 4 and the stopper 3.

The present invention is not limited to the embodiments, but can be altered by a skilled person in the art within the scope of the claims. An embodiment based on a proper combination of technical means disclosed in different embodiments is also encompassed in the technical scope of the present invention.

With a printed board holding case in accordance with the present invention, it is possible to easily insert a printed board inside a metal frame, and to fix the printed board so that the printed board is sandwiched between respective of tab sections and respective of supporting sections. This is because the printed board holding case includes a metal frame provided with the tab sections and the supporting sections, each of which protrudes inside the metal frame for containing the printed board; and each of the tab sections has elasticity so as to return to its original state after being pushed toward an inner surface of the metal frame by a force applied in an insertion direction of the printed board. Therefore, it becomes possible to improved quality and reliability of a high frequency component to be produced.

In order to attain the object, a printed board holding case in accordance with the present invention is a printed board holding case for containing a printed board inside a metal frame, the metal frame including said tab sections and said supporting sections, each of which protrudes inside the metal frame so as to fix the printed board, each of said tab sections being provided so that its height gradually becomes higher toward downstream in the insertion direction, each of said tab sections having elasticity so as to return to its original state after being pushed toward an inner side surface of the metal frame by a force applied from upstream side in the insertion direction, said supporting sections being provided downstream of said tab sections in the insertion direction, and the printed board being contained so as to be sandwiched between respective of said tab sections and respective of said supporting sections.

The printed board holding case in accordance with the present invention includes the metal frame for containing the printed board. The printed board is inserted to the printed board holding case from one side of an opening of the metal frame. The metal frame is provided with the tab sections and the supporting sections, each of which is for fixing the printed board thus inserted. The tab sections are provided upstream in the insertion direction of the printed board. The supporting sections are provided downstream in the insertion direction.

The tab sections provided on the metal frame become higher in height toward the downstream in the insertion direction in which the printed board is inserted into the metal frame. Each of the tab sections has elasticity so as to return to its original state after being pushed toward an inner side surface of the metal frame by a force applied from the upstream side in the insertion direction. The supporting sections are formed downstream of the tab sections in the insertion direction so that the printed board is fitted in between the tab sections and the supporting sections.

With the arrangement above, when the printed board is inserted into the metal frame from the opening on a side on which the tab sections are provided, the printed board comes into contact with the tab sections. Further, when a force is applied so that the printed board is sandwiched between the tab sections and the supporting sections, the printed board moves along the tab sections toward the downstream in the insertion direction. This causes the force to be applied to the tab sections from the upstream side in the insertion direction via the printed board. Each of the tab sections has a height in a direction perpendicular to the insertion direction, which height becomes higher toward the downstream in the insertion direction. In addition, each of the tab sections has elasticity in response to the force applied from the upstream side in the insertion direction. Therefore, the tab sections are gradually pushed toward the inner side surface of the metal frame by the force applied via the printed board. This causes the printed board to be contained on the downstream side in the insertion direction in the metal frame.

The force is no longer applied to the tab sections after the printed board is inserted farther than where the tab sections are provided. This causes each of the tab sections to return to its original state due to its metal elasticity. The tab sections thus returned to the original state prevent the printed board from moving in the insertion direction by supporting the printed board on the upstream side in the insertion direction. The printed board is supported by the supporting sections provided downstream of the tab sections in the insertion direction. The supporting sections prevent the printed board from moving in the insertion direction by supporting the printed board on the downstream side in the insertion direction. Therefore, the printed board can be sandwiched between and fixed by the tab sections and the supporting sections.

As described above, with the printed board holding case in accordance with the present invention, the printed board can be easily inserted; and the printed board thus inserted can be surely fixed to the case. Therefore, unlike a conventional technique, it is not necessary to carry out, after the printed board is inserted to the case, bending of tabs so that the tabs come into contact with the printed board so as to fix the printed board. This makes it possible to achieve a reduction in operation time and in cost.

It is preferable that the printed board holding case in accordance with the present invention is arranged so that at least one tab section and one supporting section are provided on at least a pair of inner surfaces of the metal frame, respectively, the pair of inner surfaces facing each other. In this arrangement, the printed board is fixed because opposed ends of the printed board are supported by the tab sections and the supporting sections so that the printed board contained inside the metal frame can maintain its balance. Therefore, the printed board can be stably contained inside the metal frame.

It is preferable that the printed board holding case in accordance with the present invention is arranged so that at least one tab section and one supporting section are provided on all of the inner surfaces of the metal frame, respectively. In this arrangement, the printed board contained inside the metal frame is supported by the tab sections and the supporting sections that are provided on all of the inner surfaces of the metal frame. Therefore, the printed board can be more stably contained inside the metal frame.

It is preferable that the printed board holding case in accordance with the present invention is arranged so that each of said tab sections has a surface downstream in the insertion direction, the surface being perpendicular to the insertion direction. In this arrangement, the surface downstream in the insertion direction can be made substantially parallel to the insertion direction by an adjustment in a bending process of the tab sections. This causes the printed board contained inside the metal frame to come into contact with a whole area (not a part) of the surface downstream in the insertion direction. This makes it possible to more surely fix the printed board inside the metal frame.

It is preferable that the printed board holding case in accordance with the present invention is arranged so that a distance in the insertion direction between respective of said tab sections and respective of said supporting sections is equal to a thickness of the printed board to be contained inside the metal frame. In this arrangement, the printed board contained inside the metal frame is sandwiched between the tab sections and the supporting sections without interspaces. By this, the printed board can be sufficiently fixed to the case without being unstable.

It is preferable that the printed board holding case in accordance with the present invention is arranged so that a distance in the insertion direction between respective of said at least one tab section and one supporting section is shorter by 0.02 mm to 0.05 mm than a thickness of the printed board to be contained inside the metal frame; and a distance in a direction perpendicular to the insertion direction between a tab section and a supporting section that are provided adjacent on a same surface of the metal frame is 5 mm to 6 mm.

In this arrangement, the printed board contained inside the metal frame is sandwiched between the tab sections and the supporting sections without interspaces, and forces of a certain level applied from both sides in the insertion direction are exerted on the printed board. Further, the forces are applied by the tab sections and the supporting sections to different positions of the printed board, respectively, so that the printed board is distorted like a spring. This prevents the printed board from being unstable inside the metal frame. Therefore, it is possible to more surely fix the printed board to the case.

It is preferable that the printed board holding case in accordance with the present invention is arranged so that a height H is greater by 0.1 mm to 0.6 mm than (L1−L2)/2, where H indicates a highest height of said at least one tab section in the direction perpendicular to the insertion direction; L1 indicates a distance between the pair of the inner surfaces on which said at least one tab section and one supporting section are formed; and L2 indicates a length of the printed board in the direction perpendicular to the insertion direction, the printed board being to be contained inside the metal frame.

In this arrangement, in a case where the printed board is inserted from an opening on a side on which the tab sections are formed, each of the tab sections having been pushed toward the inner side surface of the metal frame by the printed board returns to its original state inside the metal frame due to its metal elasticity when the printed board passes over the tab sections. This makes it possible to easily determine whether the printed board is fixed between the tab sections and the supporting sections. Therefore, the printed board can be prevented from being insufficiently inserted.

It is preferable that the printed board holding case in accordance with the present invention is arranged so that the height H is greater by 0.4 mm to 0.6 mm than (L1−L2)/2, where H indicates a highest height of said at least one tab section in the direction perpendicular to the insertion direction; L1 indicates a distance between the pair of the inner surfaces on which said at least one tab section and one supporting section are formed; and L2 indicates a length of the printed board in the direction perpendicular to the insertion direction, the printed board being to be contained inside the metal frame.

With this arrangement, an area where the tab section is in contact with the printed board contained inside the metal frame can be soldered in a sufficiently large area.

A high frequency component in accordance with the present invention is arranged so that the printed board, on which a high frequency circuit is provided, is sandwiched between respective of said tab sections and respective of said supporting sections. With this arrangement, it is possible to sufficiently fix the printed board inside the holding case and to easily produce the high frequency component.

It is preferable that the high frequency component in accordance with the present invention is arranged so that surfaces where said tab sections come in contact with the printed board are soldered. With this arrangement, it is possible to reduce impedance of the printed board because the case and the printed board are electrically connected to each other.

It is preferable that the high frequency component in accordance with the present invention is arranged so that the tab sections are soldered so as to be sandwiched between solder in a direction perpendicular to the insertion direction. With this arrangement, it is possible to prevent a crack in a soldered part due to heat cycle load.

A method for producing a high frequency component in accordance with the present invention includes inserting the printed board, on which a high frequency circuit is provided, into the metal frame from a side on which said tab sections are provided so that the printed board is sandwiched between respective of said tab sections and respective of said supporting sections.

With this method, which uses the printed board holding case in accordance with the present invention, the printed board is easily inserted into the metal frame by pushing the tab sections toward the inner side surface of the metal frame. At the moment when the printed board is inserted between the tab sections and the supporting sections, each of the tab sections returns to its original state. By this, the printed board is fixed inside the metal frame with the tab sections and the supporting sections. Therefore, it is unnecessary to carry out a bending process of the tab sections and other process after the printed board is inserted into the metal frame. This makes it possible to reduce operation time and cost for producing the high frequency component.

A method for producing a printed board holding case in accordance with the present invention is a method for producing a printed board holding case for containing a printed board inside a metal frame of the case, including the steps of: providing each of tab sections for fixing the printed board by (i) notching the metal frame so that first and second line segments are caused, each of the first and second line segments having first and second ends, the first ends coming in contact with each other, and (ii) bending the metal frame inside the metal frame along a fold line that connects the second ends of the first and second line segments, and providing supporting sections, which are for fixing the printed board, downstream of the tab sections in an insertion direction of the printed board, in the step of providing each of the tab sections, the fold line extending downstream in the insertion direction, the first ends being closer to the second end of the first line segment on the downstream side in the insertion direction.

With this method, it is possible produce such a tab section that is pushed toward the inner side surface of the metal frame by a force applied in the insertion direction by the printed board when the printed board is inserted into the metal frame, and returns to its original state due to its metal elasticity when the force is no longer applied. Further, since the tab sections are formed totally with a metal mold in a producing process of the printed board holding case, it is possible to produce a printed board holding case achieving high reliability and high accuracy in size.

A printed board holding case in accordance with the present invention, to which a printed board can be easily inserted and sufficiently fixed, is suitably applicable to production and the like of an electronic device including a board on which various circuits are provided.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

1. A printed board holding case for containing a printed board inside a metal frame of the case,
the metal frame including tab sections and supporting sections, each of which protrudes inside the metal frame so as to fix the printed board,
each of said tab sections being obtained by a notch, which causes first and second line segments in the metal frame, each of the first and second line segments having first and second ends, the first ends coming in contact with each other, and said each of the tab sections being provided so that the metal frame is bent inside the metal frame along a fold line that connects the second ends of the first and second line segments of the notch,
said supporting sections being provided downstream of said tab sections in an insertion direction of the printed board, and
the printed board being contained so as to be sandwiched between respective of said tab sections and respective of said supporting sections.

2. A printed board holding case according to claim 1, wherein:
each of said tab sections is provided so that its height gradually becomes higher toward downstream in the insertion direction; and
each of said tab sections has elasticity so as to return to its original state after being pushed toward an inner side surface of the metal frame by a force applied from upstream side in the insertion direction.

3. The printed board holding case according to claim 1, wherein at least one tab section and one supporting section are provided on at least a pair of inner surfaces of the metal frame, respectively, the pair of inner surfaces facing each other.

4. The printed board holding case according to claim 1, wherein at least one tab section and one supporting section are provided on all of the inner surfaces of the metal frame, respectively.

5. The printed board holding case according to claim 1, wherein each of said tab sections has a surface downstream in the insertion direction, the surface being perpendicular to the insertion direction.

6. The printed board holding case according to claim 1, wherein a distance in the insertion direction between respective of said tab sections and respective of said supporting sections is equal to a thickness of the printed board to be contained inside the metal frame.

7. The printed board holding case according to claim 3, wherein:
a distance in the insertion direction between respective of said at least one tab section and one supporting section is shorter by 0.02 mm to 0.05 mm than a thickness of the printed board to be contained inside the metal frame; and
a distance in a direction perpendicular to the insertion direction between a tab section and a supporting section that are provided adjacent on a same surface of the metal frame is 5 mm to 6 mm.

8. The printed board holding case according to claim 3, wherein a height H is greater by 0.1 mm to 0.6 mm than (L1−L2)/2, where H indicates a highest height of said at least one tab section in the direction perpendicular to the insertion direction; L1 indicates a distance between the pair of the inner surfaces on which said at least one tab section and one supporting section are formed; and L2 indicates a length of the printed board in the direction perpendicular to the insertion direction, the printed board being to be contained inside the metal frame.

9. The printed board holding case according to claim 8, wherein the height H is greater by 0.4 mm to 0.6 mm than (L1−L2)/2.

10. A high frequency component in which a printed board is contained inside a metal frame,
the metal frame comprising tab sections and supporting sections, each of which protrudes inside the metal frame so as to fix the printed board,
each of said tab sections being obtained by a notch, which causes first and second line segments in the metal frame, each of the first and second line segments having first and second ends, the first ends coming in contact with each other, and said each of the tab sections being provided so that the metal frame is bent inside the metal frame along a fold line that connects the second ends of the first and second line segments of the notch,
said supporting sections being provided downstream of said tab sections in an insertion direction of the printed board, and
the printed board, on which a high frequency circuit is provided, being sandwiched between respective of said tab sections and respective of said supporting sections.

11. The high frequency component according to claim 10, wherein surfaces where said tab sections come in contact with the printed board are soldered.

12. The high frequency component according to claim 11, wherein the tab sections are soldered so as to be sandwiched between solder in a direction perpendicular to the insertion direction.

13. A method for producing a high frequency component in which a printed board is contained inside a metal frame,
the metal frame comprising tab sections and supporting sections, each of which protrudes inside the metal frame so as to fix the printed board,
each of said tab sections being obtained by a notch, which causes first and second line segments in the metal frame, each of the first and second line segments having first and second ends, the first ends coming in contact with each other, and said each of the tab sections being provided so that the metal frame is bent inside the metal frame along a fold line that connects the second ends of the first and second line segments of the notch,
said supporting sections being provided downstream of said tab sections in an insertion direction of the printed board,
said method comprising the step of:
inserting the printed board, on which a high frequency circuit is provided, into the metal frame from a side on which said tab sections are provided so that the printed board is sandwiched between respective of said tab sections and respective of said supporting sections.

14. A method for producing a printed board holding case for containing a printed board inside a metal frame of the case, comprising the steps of:
providing each of tab sections for fixing the printed board by (i) notching the metal frame so that first and second line segments are caused, each of the first and second line segments having first and second ends, the first ends coming in contact with each other, and (ii) bending the metal frame inside the metal frame along a fold line that connects the second ends of the first and second line segments, and
providing supporting sections, which are for fixing the printed board, downstream of the tab sections in an insertion direction of the printed board.
